(19) United States
(12) Patent Application Publication
(10) Pub. No.: US 2005/0237832 A1
(43) Pub. Date: Oct. 27, 2005

(54) Apparatus and method for reproducing multimedia data

(75) Inventors: Min-seok Kim, Suwon-si (KR); Sung-kyoo Kim, Yongin-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., LTD., Suwon-si (KR)

(21) Appl. No.: 11/111,785

(22) Filed: Apr. 22, 2005

(30) Foreign Application Priority Data
Apr. 22, 2004 (KR) 2004-0027851

(51) Int. Cl. G11C 7/00

(52) U.S. Cl. 365/202

(57) ABSTRACT

An apparatus for and a method of reproducing multimedia data. An apparatus for reproducing multimedia data includes: a data reading unit reading stored multimedia data; a memory unit for reproducing the read multimedia data; and a control unit generating a list of the read multimedia data, establishing an area of the memory unit for reproducing multimedia data selected from the list, and reproducing selected multimedia data by using the established area.

### CROSS-REFERENCE TO RELATED APPLICATION

This application claims priority from Korean Patent Application No. 2004-0027851 filed on Apr. 22, 2004 in the Korean Intellectual Property Office, the disclosure of which is incorporated herein by reference.

### BACKGROUND OF THE INVENTION

1. Field of the Invention

The present invention relates to an apparatus for and method of reproducing multimedia data, and more particularly, to an apparatus for and method of reproducing multimedia data in which multiple types of multimedia data are simultaneously reproduced.

2. Description of Related Art

In general, multimedia data, such as image data, is recorded on a recordable optical disc like a compact disc (CD) and a digital versatile disc (DVD).

Such image data is recorded on an optical disc by using a CD writer, after being compressed by an image processing apparatus.

The optical disc including the image data is distributed to a user, and the user reproduces the image data by using a CD player or a DVD player. Such a CD player or a DVD player cannot simultaneously reproduce multiple types of multimedia data due to limited system performance and resources. In other words, for example, music data cannot be reproduced while reproducing image data. Consequently, a user reproduces the music data by using an additional data reproducing apparatus to reproduce the music data and the image data at the same time.

Korean Laid-open Patent No. 2001-0077000 discloses a method of managing audio data and additional data of a rewritable recording medium, which reproduces and displays additional still images and text data when reproducing audio data. In this case, the additional still images and text data are reproduced when reproducing audio data without considering system performance and resources that are used when reproducing the audio data. Accordingly, the system cannot generate an optimum performance.

### BRIEF SUMMARY

An aspect of the present invention provides an apparatus for and method of reproducing multimedia data for simultaneously reproducing multiple types of multimedia data, which are recorded on a storing medium.

According to an aspect of the present invention, there is provided an apparatus for reproducing multimedia data, the apparatus including: a data reading unit reading stored multimedia data; a memory unit for reproducing the read multimedia data; and a control unit generating a list of the read multimedia data, establishing an area of the memory unit for reproducing multimedia data selected from the list, and reproducing selected multimedia data by using the established area.

According to another aspect of the present invention, there is provided a method of reproducing multimedia data, the method including: reading multimedia data; providing a list of the read multimedia data, and establishing an area of a memory unit for reproducing the multimedia data selected from the list; and reproducing the selected multimedia data by using the established area of the memory unit.

According to another aspect of the present invention, there is provided an apparatus for simultaneously reproducing multiple types of multimedia data, including: a memory in which buffer areas corresponding to each type of multimedia data to be reproduced are establishable; and a control unit generating a list of read multimedia data from which the multimedia data to be reproduced are selectable, establishing buffer areas for each type of selected multimedia data, and buffering the selected multimedia data in the established buffer areas.

Additional and/or other aspects and advantages of the present invention will be set forth in part in the description which follows and, in part, will be obvious from the description, or may be learned by practice of the invention.

### BRIEF DESCRIPTION OF THE DRAWINGS

These and/or other aspects and advantages of the present invention will become apparent and more readily appreciated from the following detailed description, taken in conjunction with the accompanying drawings of which:

FIG. 1 is a block diagram of an apparatus for reproducing multimedia data according to an embodiment of the present invention;

FIG. 2 is a flowchart illustrating a method of reproducing multimedia data according to an embodiment of the present invention;

FIG. 3 is a flowchart illustrating a method of reproducing image data and music data according to an embodiment of the present invention;

FIG. 4 is a block diagram illustrating areas of a memory unit of the apparatus of FIG. 1 when reproducing one type of multimedia data according to an embodiment of the present invention; and

FIG. 5 is a block diagram illustrating areas of a memory unit of the apparatus of FIG. 1 when reproducing multiple types of multimedia data according to an embodiment of the present invention.

### DETAILED DESCRIPTION OF EMBODIMENTS

Reference will now be made in detail to embodiments of the present invention, examples of which are illustrated in the accompanying drawings, wherein like reference numerals refer to the like elements throughout. The embodiments are described below in order to explain the present invention by referring to the figures.

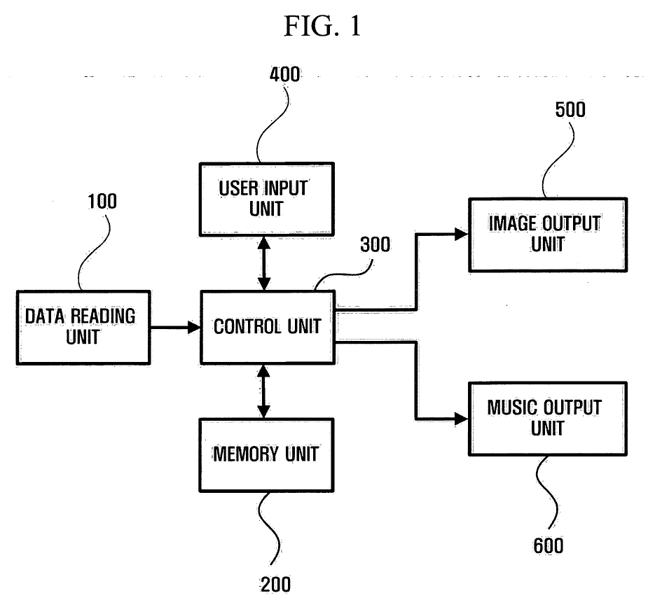

Referring to FIG. 1, an apparatus for reproducing multimedia data includes a data reading unit 100 for reading multimedia data recorded on a specified storing medium, a memory unit 200 for buffering the read multimedia data, and a control unit 300. The control unit 300 generates a multimedia data list including the read multimedia data, provides the multimedia data list to a user, buffers the selected multimedia data by using the area setting value of the memory unit 200, which is set based on the selected multimedia data, and reproduces the selected multimedia data. The value may be set preliminarily set.

In addition, the apparatus for reproducing multimedia data includes a user input unit 400 to which a selected input value corresponding to the multimedia data selected by the user via the multimedia data list is input, and an image output unit 500 and a music output unit 600 for outputting the multimedia data reproduced by the control unit 300.

Examples of the multimedia data include image data, music data, and moving picture data. In the description of the present embodiment, image data and music data are used as the multimedia data. However, it is to be understood that these and other types of multimedia data are possible and contemplated.

The control unit 300 outputs the multimedia data list through the image output unit 500, and the user may select multimedia data by using the multimedia data list.

In other words, an apparatus for reproducing multimedia data according to an embodiment of the present embodiment may be applied to a CD player or a DVD player. When a CD or a DVD including multimedia data is inserted, the control unit 300 controls the data reading unit 100 to read multimedia data from the CD or the DVD and generates a list of multimedia data recorded on the CD or the DVD based on the reading result. Alternatively, the user may search the multimedia data recorded on the CD or the DVD to select desired multimedia data. In this case, the control unit 300 may provide a multimedia data list for the multimedia data other than the selected multimedia data by the user.

Meanwhile, the control unit 300 establishes areas for buffering the selected multimedia data by using an area setting value of the memory unit 200, which may be preliminarily set according to the multimedia data selected by the user. Such a setting value is stored in a specified area of the memory unit 200 or in an additional memory, thus the control unit 300 establishes the area of the memory unit 200 by using an optimum setting value whenever the user selects the multimedia data.

For example, when a 64 MB memory unit 200 is used, the sizes of the areas for the multimedia data can be established as shown in Table 1.

TABLE 1

| Number of selected | Type of selected | Size of |
|---|---|---|
| multimedia data | multimedia data | established area |
| 1 | image data | 10 MB |
| 2 | image data | 12 MB |
| | music data | 20 MB |
| 2 | music data | 15 MB |
| | moving picture data | 25 MB |
| 2 | moving picture data | 30 MB |
| | image data | 15 MB |

Referring to Table 1, when reproducing multiple types of multimedia data at the same time while varying the sizes of the areas established in the memory unit 200 based on the kinds of the multimedia data selected by the user, an optimum performance can be obtained.

The memory unit 200 may establish an area for buffering when reproducing the multimedia data or may establish the area for buffering and an area for an application program of reproducing the buffered multimedia data.

Accordingly, the control unit 300 reproduces the buffered multimedia data through the application program and outputs the multimedia data through the image output unit 500 and the music output unit 600.

In an alternative embodiment of the present invention, when a multimedia data whose reproduction is stopped by a user exit, the control unit 300 renews the area setting value for removing the area for the stopped multimedia data to change the area established for reproducing other multimedia data.

In addition, the control unit 300 reproduces the selected multimedia data by at least one of a sequential reproducing mode, a repeated reproducing mode, and a random reproducing mode, according to the selection of the user.

For example, when the image data is referred to as the multimedia data, the image data may be reproduced in a slide show type, the same image data may be reproduced repeatedly, or the image data selected by the user may be randomly reproduced.

A method of reproducing multimedia data according to an embodiment of the present invention will now be described. The method can be performed by the apparatus of FIG. 1 and is, for ease of explanation only, described in conjunction with FIG. 1. However, it is to be understood that other apparatuses may be used to perform the subject method.

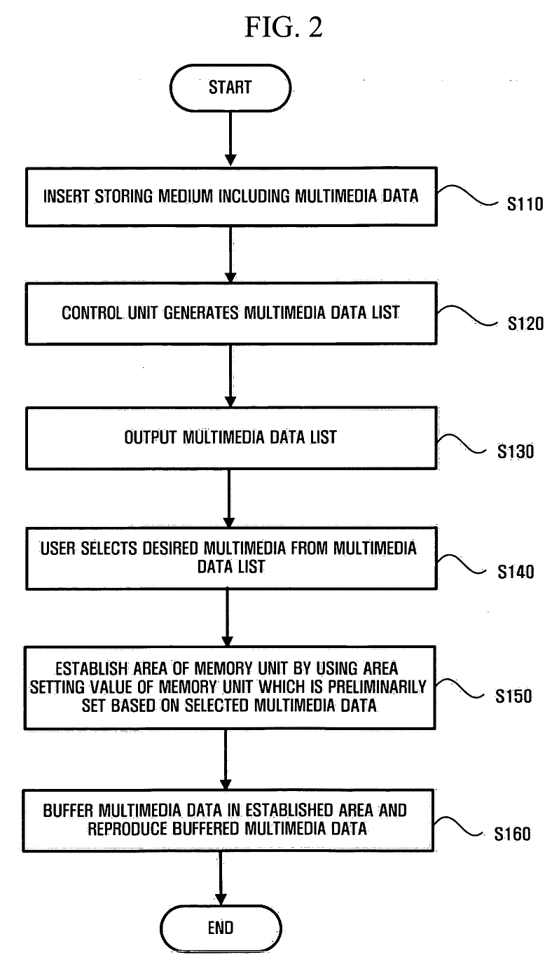

Referring to FIGS. 1 and 2, when a storing medium, such as a CD or a DVD, on which multimedia data are stored, is inserted, in operation S110, the control unit 300 controls the data reading unit 100 to read the stored multimedia data and generates a multimedia data list based on the reading result, in operation S120. In addition, the control unit 300 stores the multimedia data list in a specified area of the memory unit 200 or in an additional memory.

The control unit 300 outputs the multimedia data list through the image output unit 500, in operation S130.

A user selects desired multimedia data by using the multimedia data list, in operation S140.

The control unit 300 establishes the areas of the memory unit 200 by using an area setting value of the memory unit 200, which is preliminarily set based on the multimedia data selected by the user, in operation S150. In other words, the control unit 300 establishes the memory area for each kind of multimedia data by using the preliminarily set setting value, which is shown in Table 1, based on the multimedia data selected by the user.

The control unit 300 buffers the multimedia data in the area, which is set in the area setting value, and reproduces the buffered multimedia data, in operation S160.

In this case, when an application program of reproducing the multimedia data is stored in the memory unit 200, the control unit 300 reproduces the multimedia data by using the application program and outputs the multimedia data through the image output unit 500 and the music output unit 600.

A method of reproducing multimedia data according to an embodiment of the present invention will now be described in detail. The method can be performed by the apparatus of FIG. 1 and is, for ease of explanation only, described in conjunction with FIG. 1. However, it is to be understood that other apparatuses may be used to perform the subject method.

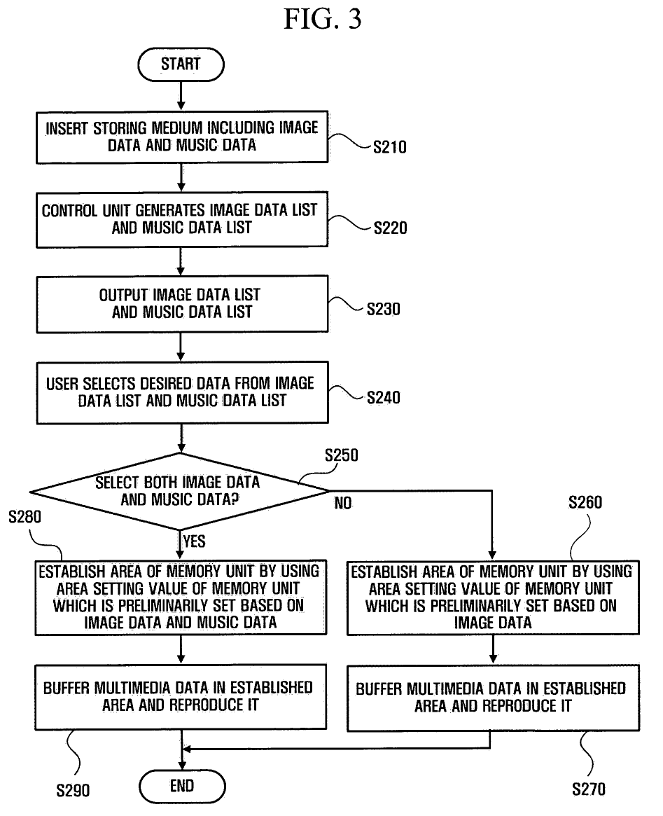

In the method of FIG. 3, the multimedia data stored on a storing medium are formed of image data and music data.

Referring to FIGS. 1 and 3, when inserting a storing medium, such as a CD or a DVD, on which image data and music data are stored, in operation S210, the control unit 300 controls the data reading unit 100 to read the image data and the music data from the storing medium and generates an image data list and a music data list based on the reading result, in operation S220.

The image data list and the music data list may be stored in a specified area of the memory unit 200 or in an additional memory.

The control unit 300 outputs the image data list and the music data list through the image output unit 500, in operation S230.

A user selects desired data from the image data list and the music data list by using the user input unit 400, in operation S240. In this case, the user may select at least one of the image data and the music data.

The control unit 300 determines the data selected by the user, in operation S250.

When the user selects the image data, the control unit 300 buffers the image data in the memory unit 200 by using an area setting value of the memory unit 200, which is preliminarily set based on the image data, in operation S260.

For example, when the size of the memory unit 200 is 64 MB as show in Table 1, a 10 MB area may be set for the selected image data, and the size of the area may be changed.

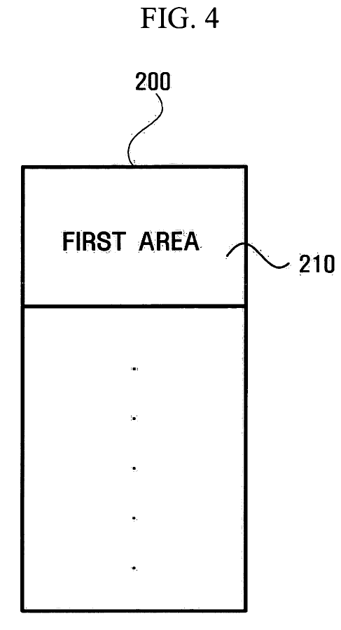

In other words, a first area 210 having a size of 10 MB may be established in the memory unit 200, as shown in FIG. 4.

In the description of the present embodiment of the present invention, the user selects image data; however, the same process may be performed when the user selects music data.

The control unit 300 reproduces the buffered image data and outputs through the image output unit 500, in operation S270.

When the control unit 300 determines that the user selects both the image data and the music data, the control unit 300 buffers the image data and the music data in the memory unit 200 by using the area setting value of the memory unit 200, which is preliminarily set based on the image data and the music data, in operation S280.

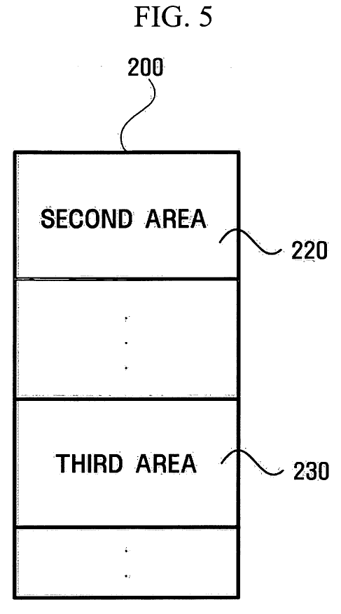

For example, when the size of the memory unit 200 is 64 MB as shown in Table 1, the areas of 12 MB and 20 MB may be established for the image data and the music data, respectively, and the sizes of the areas may be changed. In other words, a second area 220 and a third area 230 having sizes of 12 MB and 20 MB are established in the memory unit, as shown in FIG. 5.

The control unit 300 reproduces the buffered image data and music data to output through the image output unit 500 and a music output unit 600, respectively, in operation S290.

According to the above-described embodiments of the present invention, multiple types of data stored on a multimedia data storing medium may be reproduced simultaneously, thus increased utility may be realized and increased user demands may be satisfied.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. An apparatus for reproducing multimedia data, the apparatus comprising:
a data reading unit reading stored multimedia data;
a memory unit for reproducing the read multimedia data; and
a control unit generating a list of the read multimedia data, establishing an area of the memory unit for reproducing multimedia data selected from the list, and reproducing selected multimedia data by using the established area.

2. The apparatus of claim 1, wherein the established area of the memory unit is established by using a preliminarily set value.

3. The apparatus of claim 2, wherein the set value is stored in the memory unit or in an additional memory.

4. The apparatus of claim 1, wherein the memory unit is 64 megabytes (MB) and the control unit establishes areas for each type of selected multimedia data, and wherein, when a number of selected multimedia data is 1 and the type of selected multimedia data is image data, the size of the established area is 10 MB, when a number of selected multimedia data is 2 and the types of selected multimedia data are image data and music data, the sizes of the established areas are respectively 12 MB and 20 MB, when a number of selected multimedia data is 2 and the types of selected multimedia data are music data and moving picture data, the sizes of the established areas are respectively 15 MB and 25 MB, and when a number of selected multimedia data is 2 and the types of selected multimedia data are moving picture data and image data, the sizes of the established areas are respectively 30 MB and 15 MB.

5. The apparatus of claim 1, wherein the establishment of the area in the memory unit is performed when a plurality of multimedia data are selected from the list and at least one of the selected multimedia data is reproduced by using the established area.

6. The apparatus of claim 5, wherein the establishment of the area in the memory unit is performed when a number of the types of the selected multimedia data is at least 2.

7. The apparatus of claim 6, further comprising a user input unit receiving a selected input value for the multimedia data selected by the user from the multimedia data list.

8. The apparatus of claim 7, wherein the control unit reproduces the selected multimedia data by using a sequential reproducing mode, a random reproducing mode, or a repeated reproducing mode.

9. The apparatus of claim 8, wherein the control unit renews a setting value of establishing the area of the memory unit when the reproduction of the selected multimedia data is stopped.

10. The apparatus of claim 1, wherein the stored multimedia data is stored on a storing medium.

11. The apparatus of claim 1, further comprising an image output unit outputting video data of the reproduced multimedia data and a music output unit outputting audio data of the reproduced multimedia data.

12. A method of reproducing multimedia data, the method comprising:
reading multimedia data;
providing a list of the read multimedia data; and
establishing an area of a memory unit for reproducing the multimedia data selected from the list and reproducing the selected multimedia data by using the established area of the memory unit.

13. The method of claim 12, wherein the established area of the memory unit is established by using a preliminarily set value.

14. The method of claim 12, wherein the establishment of the area in the memory unit is performed when a plurality of multimedia data are selected from the list and at least one of the selected multimedia data is reproduced by using the established area.

15. The apparatus of claim 14, wherein the establishment of the area in the memory unit is performed when a number of the types of the selected multimedia data is at least 2.

16. The method of claim 15, wherein the selected multimedia data is reproduced by a sequential reproducing mode, a random reproducing mode, and a repeated reproducing mode.

17. The method of claim 12, further comprising renewing a setting value of establishing the area of the memory unit when the reproduction of the selected multimedia data is stopped.

18. An apparatus for simultaneously reproducing multiple types of multimedia data, comprising:
a memory in which buffer areas corresponding to each type of multimedia data to be reproduced are establishable; and
a control unit generating a list of read multimedia data from which the multimedia data to be reproduced are selectable, establishing buffer areas for each type of selected multimedia data, and buffering the selected multimedia data in the established buffer areas.
